(19) United States
(12) Patent Application Publication
(10) Pub. No.: US 2013/0037695 A1
(43) Pub. Date: Feb. 14, 2013

(54) IMAGE PICK-UP APPARATUS

(71) Applicant: CHUN-YU LEE, Tu-Cheng (TW)

(72) Inventor: CHUN-YU LEE, Tu-Cheng (TW)

(73) Assignee: HON HAI PRECISION INDUSTRY CO., LTD., Tu-Cheng (TW)

(21) Appl. No.: 13/533,983

(22) Filed: Jun. 27, 2012

(30) Foreign Application Priority Data
Aug. 11, 2011 (TW) 100128666

(51) Int. Cl. H01L 27/146

(52) U.S. Cl. 250/208.1

(57) ABSTRACT

An image pick-up apparatus includes a lens module, a base plate and an image sensor. The lens module includes a lens barrel and an optical lens. The optical lens has an optical axis. The base plate has a first surface facing toward the lens module, and an opposite second surface. The base plate has a through hole through the first and second surfaces. The through hole includes a first hole adjacent to the lens module and a second hole away from the lens module. The first hole is in communication with the second hole. The first hole has a first hole portion with a rectangular cross section. Inner surfaces of the first hole portion is inclined relative to the optical axis. An image sensor received in the second hole. The optically effective region of the image sensor has a smaller area than the opening of the first hole.

### BACKGROUND

1. Technical Field

The present disclosure relates generally to an image pick-up apparatus having a lens module and an image sensor.

2. Description of Related Art

Image pick-up apparatuses are used in a variety of consumer electronic devices, such as notebook computers, personal digital assistants (PDAs), and cellular telephones. An image pick-up apparatus includes a lens module, a base plate and an image sensor mounted on the base plate. The lens module includes a lens barrel and a number of lenses received in the lens barrel. The base plate is fixed to an end of the lens barrel, and defines a through hole for exposing an optically effective region of the image sensor and allowing light to be transmitted from the lens module onto the effective region of the image sensor. Generally, the effective region of the image sensor has a larger area than that of the through hole. Thus, an inner wall of the base plate adjacent to the through hole may reflect light back onto the effective region of the image sensor, which may cause glare during the capturing of the image.

Therefore, there is a need for an image pick-up apparatus, to overcome the above mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a sectional view of an image pick-up apparatus according to a first exemplary embodiment, comprising a base plate and an image sensor fixed together.

FIG. 2 is a schematic, isometric view of the base plate of FIG. 1.

FIG. 3 is a front view of the base plate and the image sensor fixed together as in FIG. 1.

FIG. 4 is a sectional view of an image pick-up apparatus according to a second exemplary embodiment, comprising a base plate and an image sensor fixed together.

FIG. 5 is a front view of the base plate and the image sensor fixed together as in FIG. 4.

FIG. 6 is a sectional view of an image pick-up apparatus according to a third exemplary embodiment, comprising a base plate and an image sensor fixed together.

FIG. 7 is a front view of the base plate and the image sensor fixed together as in FIG. 6.

### DETAILED DESCRIPTION

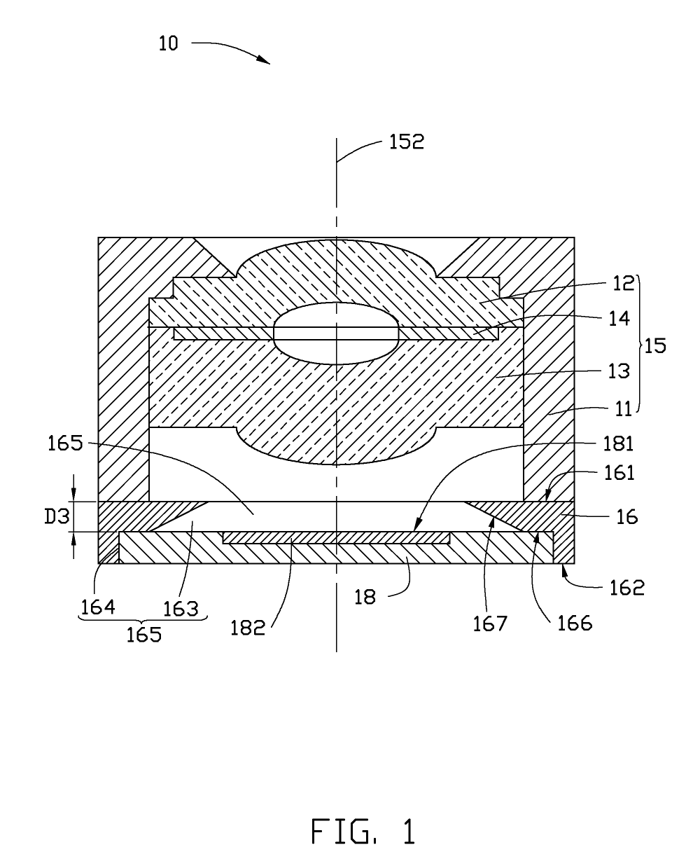

FIG. 1, is an image pick-up apparatus 10 according to a first exemplary embodiment including a lens module 15, a base plate 16, and an image sensor 18. The lens module 15 includes a lens barrel 11, a first optical lens 12, a second optical lens 13, and a light shielding plate 14.

The first optical lens 12 and the second optical lens 13 are optically aligned with each other about an optical axis 152. The light shielding plate 14 is arranged between the first and second optical lenses 12 and 13 and is aligned with the first and second optical lenses 12 and 13 along the optical axis 152. The first optical lens 12, the second optical lens 13, and the light shielding plate 14 are received in the lens barrel 11. The first and second optical lenses 12 and 13 focus passing light.

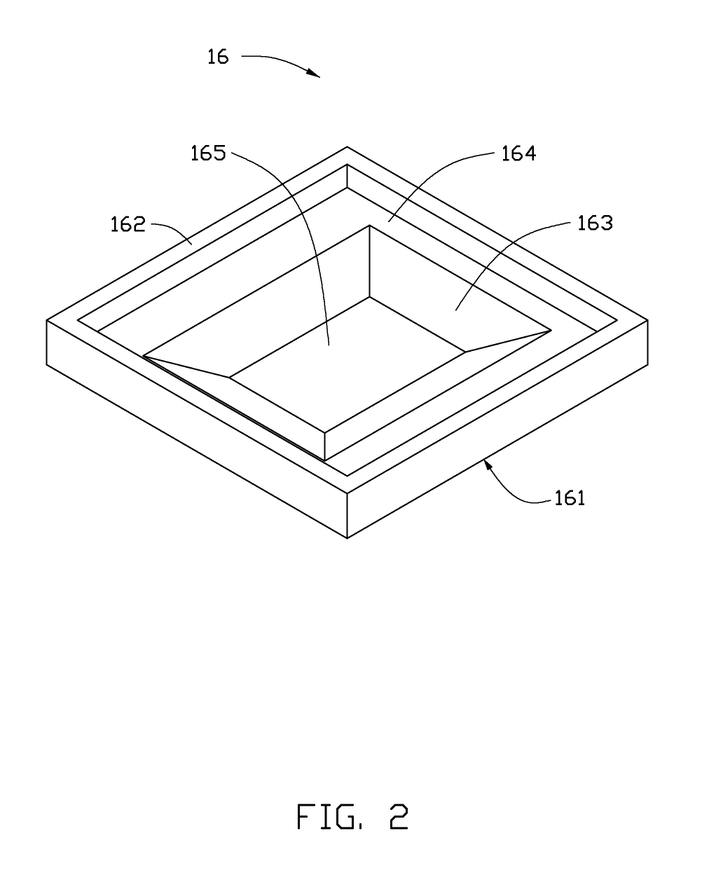

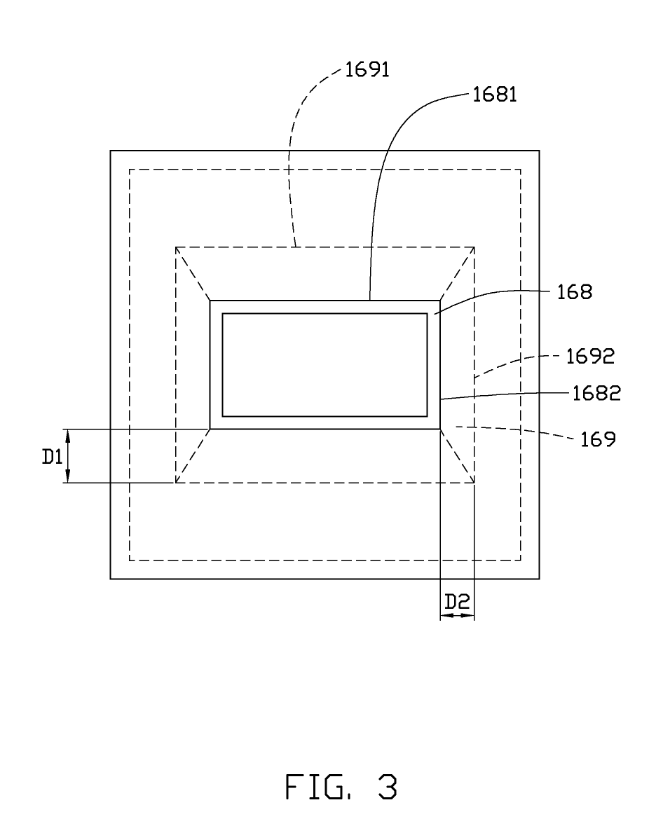

FIGS. 2 and 3, illustrate the base plate 16 has a first surface 161, an opposite second surface 162 and an through hole 165 defined through the first surface 161 and the second surface 162. The through hole 165 includes a first hole 163 adjacent to the first surface 161, and a second hole 164 adjacent to the second surface 162. The first hole 163 and the second hole 164 each have a rectangular cross section. The first hole 163 and the second hole 164 are aligned with each other along the optical axis 152 and in communication with each other. The second hole 164 has a shape of rectangular parallelepiped. The first hole 163 tapers away from the second hole 164. In an alternative embodiment, the first hole 163 can also taper away from the first surface 161. In this embodiment, the base plate 16 is comprised of ceramic material.

The first hole 163 has a first cross section 168 taken along the first surface 161. The first cross section 168 has two opposite, parallel first long sides 1681, and two opposite, parallel first short sides 1682. The first hole 163 has a second cross section 169 taken along a border between the first and second holes 163 and 164 smaller than that of the second hole 164, thereby an inner step surface 166 is formed in the through hole 165 at a border between the first and second holes 163 and 164. The first hole 163 tapers from the inner step surface 166 to the first surface 161. The second cross section 169 has two opposite, parallel second long sides 1691 parallel to the first long sides 1681, and two opposite, parallel second short sides 1692 parallel to the first short sides 1682. A first distance D1 is defined between the projections of the neighboring first and second long sides 1681 and 1691 on a plane perpendicular to the optical axis 152. A second distance D2 is defined between the projections of the neighboring first and second short sides 1682 and 1682 on a plane perpendicular to the optical axis 152.

The image sensor 18 is fixed in the second hole 164 of the base plate 16. In this embodiment, the image sensor 18 is fixed to the base plate 16 by soldering. The image sensor 18 has a top surface 181 facing the lens module 15 and a rectangular optically effective region 182 defined in the top surface 181. The optically effective region 182 is aligned with the through hole 165 about the optical axis 152 and has a smaller area than the opening of the first hole 163 of the through hole 165. The optically effective region 182 captures images. A third distance D3 is defined between the first surface 161 of the base plate 16 and the top surface 181 of the image sensor 18 along the optical axis 152. In this embodiment, the first and third distances Dl and D3 satisfy the following condition: D1>0.47×D3/8000, and the second and third distances D2 and D3 satisfy the following condition: D2>0.27×D3/8000.

In this embodiment, because the effective region 182 has a smaller area than that of the first hole 163, less light can reach the surface of the base plate 16 in the through hole 165. Also, most of light, striking inner surfaces 167 of the base plate 16 in the first hole 163 is reflected by the inner surface 167, and less light is reflected onto the effective region 182. Thus, less light is reflected by the surfaces in the through holes 165 onto the effective region 182 of the image sensor 18 and thereby, any glare present in the image pick-up apparatus 10 is effectively reduced.

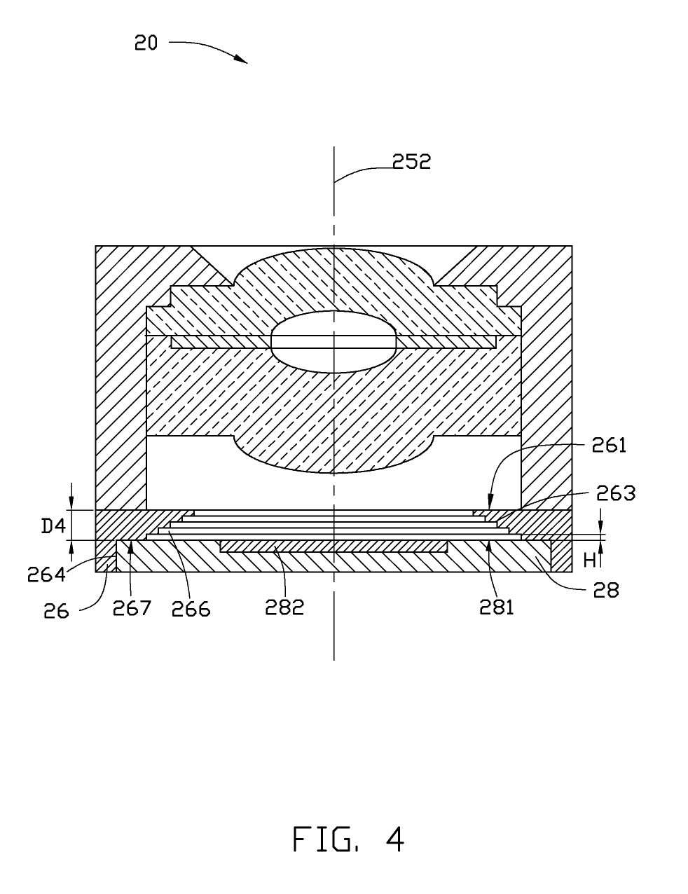

FIG. 4 is an image pick-up apparatus 20 according to a second exemplary embodiment. The distinguishing features between the image pick-up apparatus 20 and the image pick-up apparatus 10 are that a base plate 26 of the image pick-up apparatus 20 has a first hole 263 different from the first hole 163 of the image pick-up apparatus 10. The first hole 263 comprises a plurality of aligned hole sections 266. The hole sections 266 have rectangular cross-sections having widths gradually decreasing from an inner step surface 267 between the first hole 263 and a second hole 264 of the base plate 26 to the first surface 261. The hole section 266 with the smallest cross-section is larger than the optically effective region 282. The rectangular holes 266 have equal lengths H along the optical axis 152. It is noted that the depths H of the rectangular holes 266 can also be different. A fourth distance D4 is defined between the first surface 261 and a top surface 281 of an image sensor 28 of the image pick-up apparatus 20 along an optical axis 252 of the image pick-up apparatus 20. Each of the depths H of the rectangular holes 266 and the fourth distance D4 satisfy the following condition: H>D4/1000. An optically effective region 282 of the image sensor 28 is aligned with the first hole 263 about the optical axis 252 of the image pick-up apparatus 20 and has a smaller area than the opening of the first hole 263.

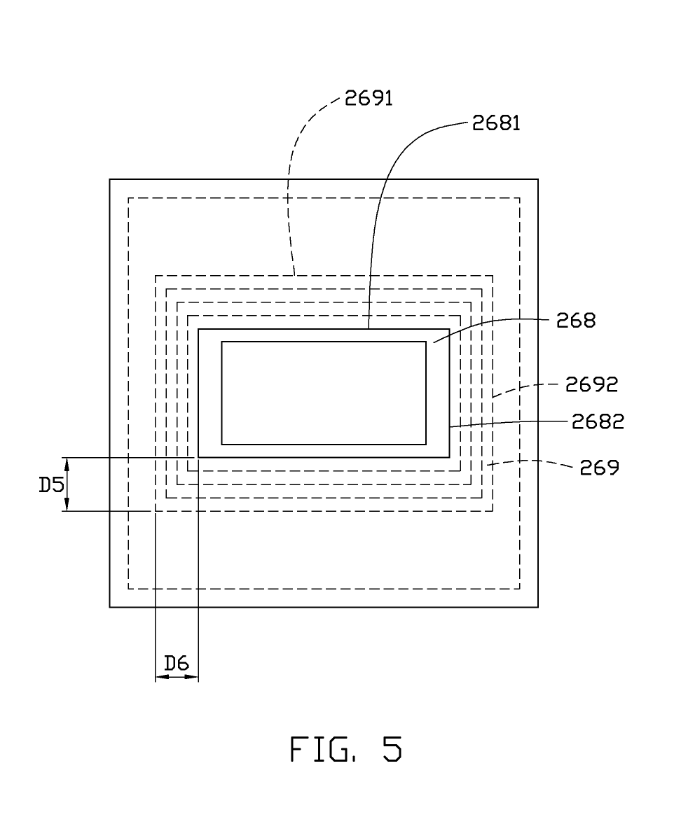

FIG. 5 illustrates the first hole 263 has a first cross section 268 taken along the first surface 261. The first cross section 268 has two opposite, parallel first long sides 2681, and two opposite, parallel first short sides 2682. The first hole 263 has a second cross section 269 taken along a border between the first and second holes 263 and 264. The second cross section 269 has two opposite, parallel second long sides 2691 parallel to the first long sides 2681, and two opposite, parallel second short sides 2692 parallel to the first short sides 2682. A fifth distance D5 is defined between the projections of the neighboring first and second long sides 2681 and 2691 on a plane perpendicular to the optical axis 252. A sixth distance D6 is defined between the projections of the neighboring first and second short sides 2682 and 2682 on a plane perpendicular to the optical axis 252. In this embodiment, the fourth and fifth distances D4 and D5 satisfy the following condition: D5>0.47×D4/8000, and the fourth and sixth distances D4 and D6 satisfy the following condition: D6>0.27×D4/8000.

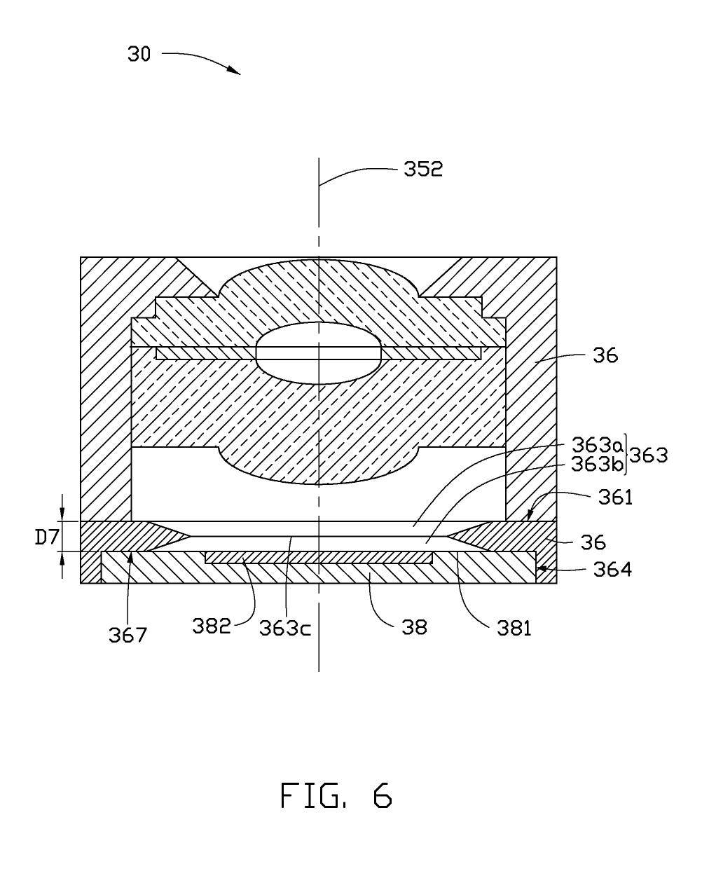

FIG. 6, is an image pick-up apparatus 30 according to a second exemplary embodiment. The distinguishing features between the image pick-up apparatus 30 and the image pick-up apparatus 10 are that a base plate 36 of the image pick-up apparatus 30 has a first hole 363 different from the first hole 163 of the image pick-up apparatus 10. The first hole 363 includes a first hole portion 363a adjacent to a first surface 361 of the base plate 363 facing a lens module 36 of the image pick-up apparatus 30 and a second hole portion 363b adjacent to a border 367 between the first hole 363 and a second hole 364 of the base plate 36. The first hole portion 363a and the second hole portion 363b are aligned with and in communication with each other, to create (in section) an internal knife edge. An interface 363c between the first hole portion 363a and the second hole portion 363b is formed between the first surface 361 and the border 367. The first hole portion 363a tapers from the first surface 361 to the interface 363c, and the second hole portion 363b tapers from border 367 to the interface 363c. The first hole portion 363a and the second hole portion 363b align with each other about an optical axis 352 of the image pick-up apparatus 30, and each have a rectangular cross section. An optically effective region 382 of an image sensor 38 of the image pick-up apparatus 30 has a smaller area than the opening of the first hole 363. A seventh distance D7 is defined between the first surface 361 and a top surface 381 of the image sensor 38 along the optical axis 352.

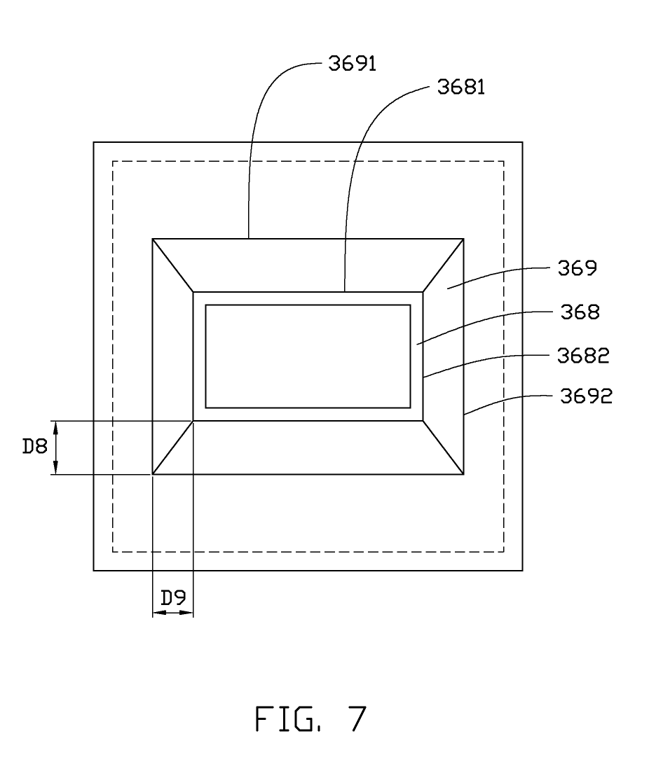

FIG. 7, illustrates the first hole 363 has a first cross section 368 taken along the first surface 361. The first cross section 368 has two opposite, parallel first long sides 3681, and two opposite, parallel first short sides 3682. The first hole 363 has a second cross section 369 taken along the interface 363c. The second cross section 369 has two opposite, parallel second long sides 3691 parallel to the first long sides 3681, and two opposite, parallel second short sides 3692 parallel to the first short sides 3682. An eighth distance D8 is defined between the projections of the neighboring first and second long sides 3681 and 3691 on a plane perpendicular to the optical axis 352. A ninth distance D9 is defined between the projections of the neighboring first and second short sides 3682 and 3682 on a plane perpendicular to the optical axis 352. In this embodiment, the seventh and eighth distances D7 and D8 satisfy the following condition: D8>0.47×D7/8000, and the seventh and ninth distances D7 and D9 satisfy the following condition: D9>0.27×D7/8000. In this embodiment, a cross section of the first hole 363 taken along the border 367 between the first and second holes 363 and 364 is equal to the first cross section 368.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An image pick-up apparatus comprising:
a lens module comprising a lens barrel and an optical lens, the optical lens having an optical axis;
a base plate having a first surface facing toward the lens module, and an opposite second surface, the base plate having a through hole through the first and second surfaces, the through hole being aligned with the optical axis, the through hole comprising a first hole adjacent to the lens module and a second hole away from the lens module, the first hole being in communication with the second hole, the first hole having a first hole portion with a rectangular cross section, inner surfaces of the first hole portion being inclined relative to the optical axis; and
an image sensor received in the second hole, the image sensor having a top surface facing the lens module, the image sensor including a rectangular optically effective region configured for capturing images, the optically effective region being aligned with the first hole and having a smaller area than the opening of the first hole.

2. The image pick-up apparatus of claim 1, wherein an inner step surface is formed in the through hole at a border between the first and second holes, and the first hole portion extends from the inner step surface toward the first surface and terminates at the first surface.

3. The image pick-up apparatus of claim 2, wherein the first hole portion tapers from the inner step surface to the first surface.

4. The image pick-up apparatus of claim 3, wherein the first hole has a first cross section taken along the first surface, the first cross section having two opposite, parallel first long sides, and two opposite, parallel first short sides, the first hole having a second cross section taken along the inner step surface, the second cross section having two opposite, parallel second long sides parallel to the first long sides, and two opposite, parallel second short sides parallel to the first short sides, wherein a first distance D1 is defined between the projections of the neighboring first and second long sides on a plane perpendicular to the optical axis, a second distance D2 is defined between the projections of the neighboring first and second short sides on the plane perpendicular to the optical axis, a distance D3 is defined between the first surface and the top surface along the optical axis, the first and third distances D1 and D3 satisfy the following condition: D1>0.47×D3/8000, the second and third distances D2 and D3 satisfy the following condition: D2>0.27×D3/8000.

5. The image pick-up apparatus of claim 2, wherein the first hole portion comprises a plurality of aligned hole sections, having rectangular cross-sections having widths gradually decreasing from the inner step surface to the first surface, the hole section with the smallest cross-section is larger than the optically effective region.

6. The image pick-up apparatus of claim 5, wherein a distance D is defined between the first surface and the top surface along the optical axis, and each of the hole sections having a length H satisfies the following condition: H>D/1000.

7. The image pick-up apparatus of claim 5, wherein the first hole has a first cross section taken along the first surface, the first cross section having two opposite, parallel first long sides, and two opposite, parallel first short sides, the first hole having a second cross section taken along the inner step surface, the second cross section having two opposite, parallel second long sides parallel to the first long sides, and two opposite, parallel second short sides parallel to the first short sides, a first distance D1 is defined between the projections of the neighboring first and second long sides on a plane perpendicular to the optical axis, a second distance D2 is defined between the projections of the neighboring first and second short sides on the plane perpendicular to the optical axis, a distance D3 defined between the first surface and the top surface along the optical axis, the first and third distances D1 and D3 satisfy the following condition: D1>0.47×D3/8000, the second and third distances D2 and D3 satisfy the following condition: D2>0.27×D3/8000.

8. The image pick-up apparatus of claim 1, wherein the first hole further comprises a second hole portion, the first hole portion being adjacent to the first surface, the second being adjacent to the second surface, the first hole portion and the second hole portion being aligned with and in communication with each other, and forming an interface between the first and second hole portions, the first hole portion tapering from the first surface to the interface, the second hole portion tapering in an opposite direction relative to the tapering of the first hole portion.

9. The image pick-up apparatus of claim 8, wherein the first hole has a first cross section taken along the first surface, the first cross section having two opposite, parallel first long sides, and two opposite, parallel first short sides, the first hole having a second cross section taken along the interface, the second cross section having two opposite, parallel second long sides parallel to the first long sides, and two opposite, parallel second short sides parallel to the first short sides, a first distance Dl is defined between the projections of the neighboring first and second long sides on a plane perpendicular to the optical axis, a second distance D2 is defined between the projections of the neighboring first and second short sides on the plane perpendicular to the optical axis, a distance D3 is defined between the first surface and the top surface along the optical axis, the first and third distances D1 and D3 satisfy the following condition: D1>0.47×D3/8000, the second and third distances D2 and D3 satisfy the following condition: D2>0.27×D3/8000, a cross section of the first hole taken along a border between the first hole and the second hole being equal to the first cross section.
